(19) United States
(12) Patent Application Publication
(10) Pub. No.: US 2026/0323903 A1
(43) Pub. Date: Oct. 15, 2026

(54) MEMORY CELL, SEMICONDUCTOR DEVICE, AND FABRICATION METHOD THEREOF

(71) Applicant: Taiwan Semiconductor Manufacturing Company, Ltd., Hsinchu (TW)

(72) Inventors: Chia-Yu Ling, Hsinchu City (TW); Katherine H. CHIANG, New Taipei City (TW)

(73) Assignee: Taiwan Semiconductor Manufacturing Company, Ltd., Hsinchu (TW)

(21) Appl. No.: 19/178,881

(22) Filed: Apr. 15, 2025

(51) Int. Cl. H10B 12/00

(52) U.S. Cl. CPC H10B 12/00

(57) ABSTRACT

A memory cell, a semiconductor device, and a fabrication method thereof are provided. The semiconductor device includes a first signal line, a spacer layer, a second signal line, a first transistor, a metal-insulator-metal (MIM) capacitor, and a second transistor. The first signal line, the spacer layer, and the second signal line are stacked along a first direction. The spacer layer is located between the first signal line and the second signal line. The first transistor extends through the first signal line and the second signal line. The MIM capacitor is disposed over the first transistor. The second transistor is disposed over the MIM capacitor. The MIM capacitor is disposed between and electrically connected to the first transistor and the second transistor.

### BACKGROUND

Memory devices are electronic components designed for data storage and are widely utilized in various electronic products, such as computers, smartphones, and servers. Based on access methods and characteristics, memory devices can be categorized into different types, including random access memory (RAM), read-only memory (ROM), and non-volatile memory (such as NAND and NOR flash memory).

Memory cells are the fundamental units of memory devices, and their design and structure vary depending on the type of memory. With the continuous advancement of semiconductor technology, the development of memory devices is progressing toward higher storage density, reduced power consumption, and enhanced durability. Among these advancements, the miniaturization of memory cells has become a critical pathway to achieving high-density storage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a diagrammatic three-dimensional view of a memory device in accordance with an embodiment of the present disclosure.

FIG. 1B illustrates a cross-sectional view of the memory device along a line A-A’ in FIG. 1A.

FIG. 1C illustrates a cross-sectional view of the memory device along a line B-B’ in FIG. 1A.

FIG. 1D illustrates a cross-sectional view of the memory device along a line C-C’ in FIG. 1A.

FIG. 1E illustrates a cross-sectional view of the memory device along a line D-D’ in FIG. 1A.

FIG. 1F illustrates a cross-sectional view of the memory device along a line E-E’ in FIG. 1A.

FIG. 1G illustrates a cross-sectional view of the memory device along a line F-F’ in FIG. 1A.

FIG. 1H illustrates a schematic circuit diagram of a memory device in accordance with an embodiment of the present disclosure.

FIGS. 2A-2P illustrate cross-sectional views of various stages in a fabricating method for a memory cell according to some embodiments of the present disclosure.

FIGS. 3A-3P illustrate perspective top views of various stages in a fabricating method for a memory cell according to some embodiments of the present disclosure.

FIG. 4 illustrates a cross-sectional view of a memory cell according to some embodiments of the present disclosure.

FIGS. 5A and 5B illustrate cross-sectional views of various stages in a fabricating method for a memory cell according to some embodiments of the present disclosure.

FIG. 6 illustrates a cross-sectional view of a memory cell according to some embodiments of the present disclosure.

FIG. 7 illustrates a cross-sectional view of a memory cell according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

This disclosure provides a semiconductor device that can, for example, be used as a memory cell in a dynamic random-access memory (DRAM) device. The disclosed semiconductor device includes a first transistor, a metal-insulator-metal (MIM) capacitor, and a second transistor overlapping in a first direction, wherein the MIM capacitor is electrically connected to the first transistor and the second transistor. The semiconductor device disclosed herein offers the advantage of a compact size, enabling increased memory cell density. In some embodiments, the disclosed semiconductor device can be fabricated during the back-end-of-line (BEOL) process. This approach, as opposed to fabrication during the front-end-of-line (FEOL) process, offers the advantage of reducing data loss because devices formed during the FEOL process are more prone to issues such as device leakage (e.g., subthreshold leakage, gate leakage, and junction leakage). The various embodiments of this disclosure will be described below in conjunction with the accompanying drawings.

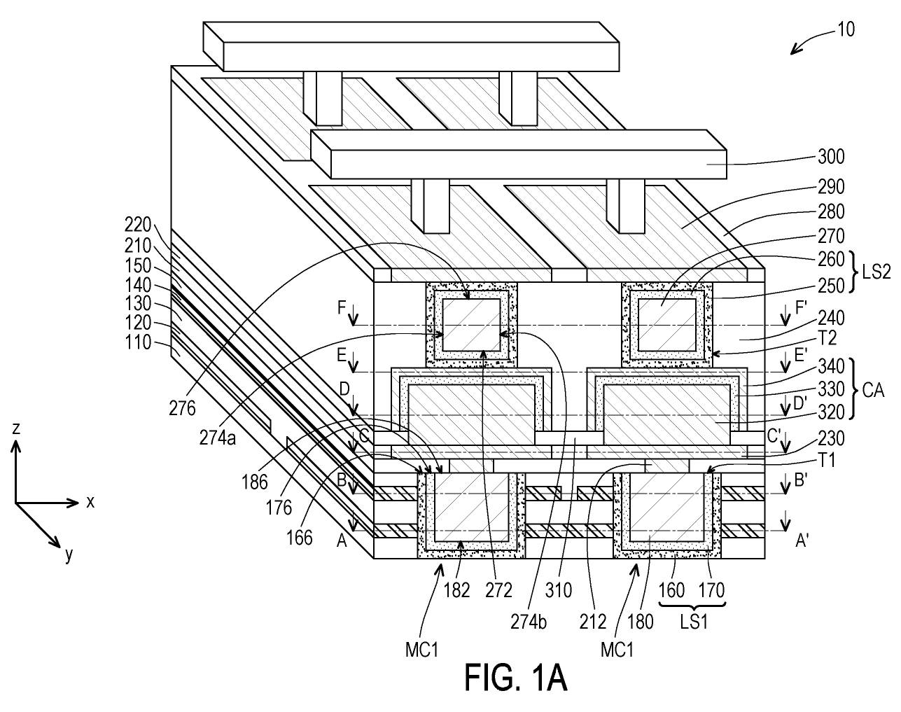

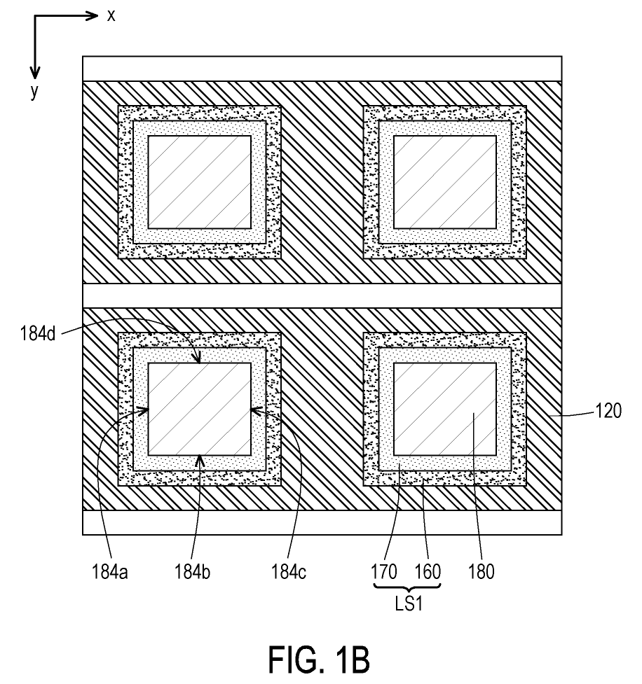

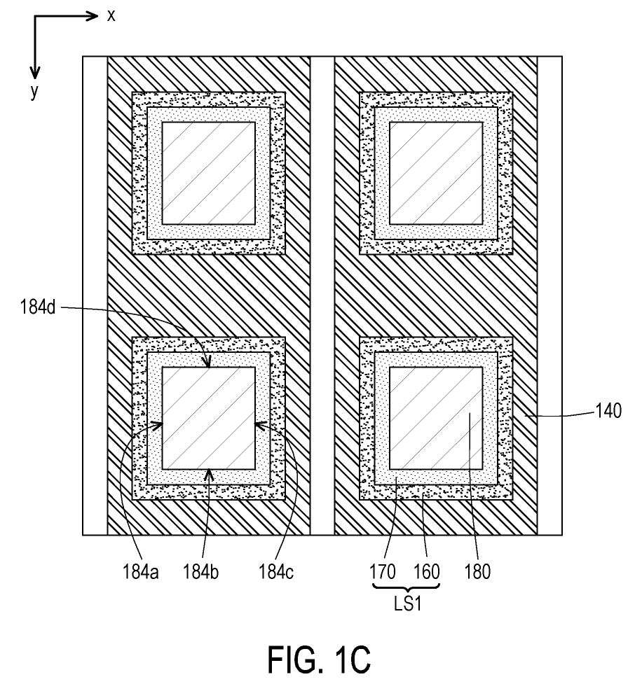

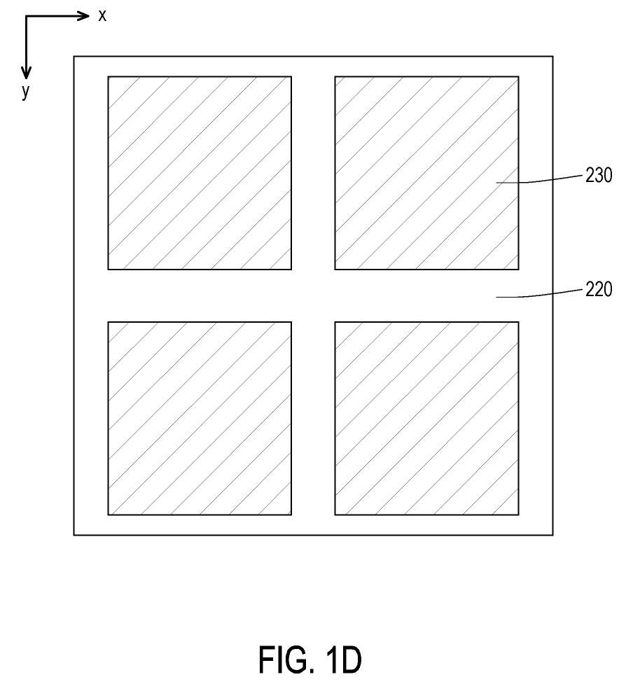

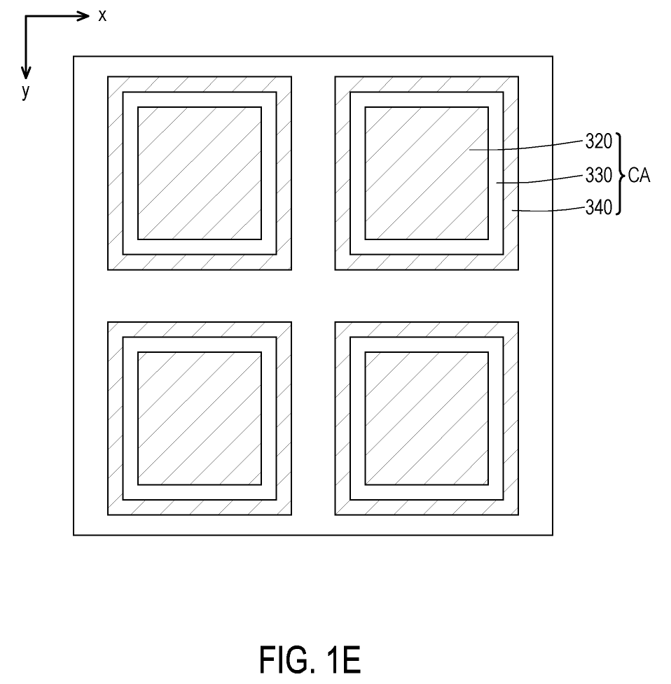

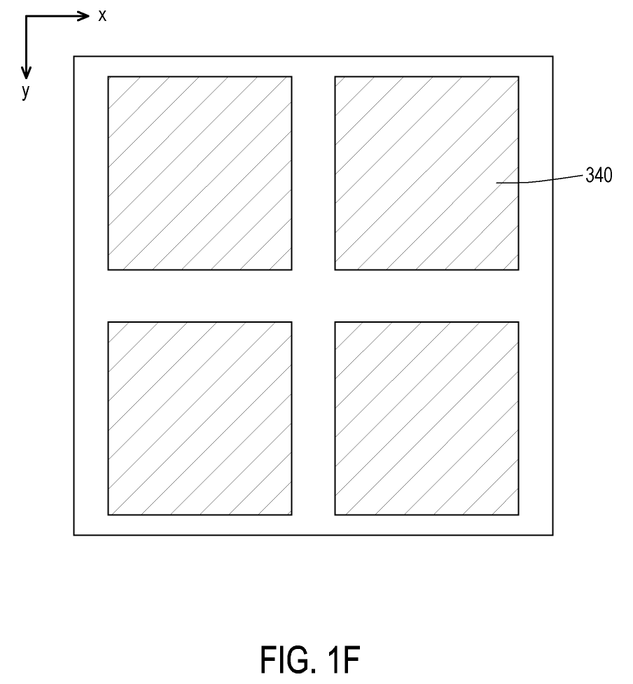

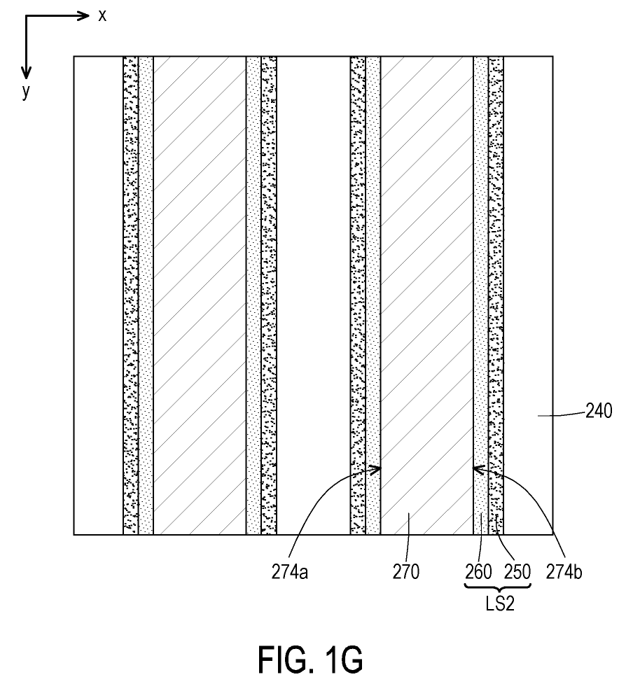

FIG. 1A illustrates a diagrammatic three-dimensional view of a memory device 10 in accordance with an embodiment of the present disclosure. FIGS. 1B-1G illustrate cross-sectional views of the memory device 10 along lines A-A’ to F-F’ in FIG. 1A, respectively. FIG. 1H illustrates a schematic circuit diagram of a memory device in accordance with an embodiment of the present disclosure. Referring to FIGS. 1A-1G, the memory device 10 includes memory cells MC1 arranged in an array. The number of the memory cells MC1 can be adjusted as needed.

Each memory cell MC1 includes a first transistor T1, a MIM capacitor CA, and a second transistor T2 overlapping with each other in a first direction z. In some embodiments, additional structures (not shown in the FIG. 1A) are included beneath the first transistor T1. For example, both the first transistor T1 and the second transistor T2 are formed in the BEOL process, while beneath the first transistor T1, a structure formed in the FEOL process is included.

First signal lines 120 and second signal lines 140 are arranged around the first transistors T1. For example, the first signal lines 120 are formed on the bottom insulating layer 110. The spacer layer 130 is disposed over both the first signal lines 120 and the bottom insulating layer 110. The second signal lines 140 are disposed over the spacer layer 130. The spacer layer 130 is positioned between the first signal lines 120 and the second signal lines 140. The second signal lines 140 partially overlap with the first signal lines 120 in the first direction z, while the first and second signal lines 120 and 140 are kept separated from each other. The top insulating layer 150 is located over the second signal lines 140. The bottom insulating layer 110, the first signal lines 120, the spacer layer 130, the second signal lines 140, and the top insulating layer 150 are sequentially stacked along the first direction z.

In this embodiment, the first signal lines 120 extend along the second direction x, which is perpendicular to the first direction z, and the second signal lines 140 extend along the third direction y, which is also perpendicular to the first direction z. In other embodiments, the first signal lines 120 extend along the third direction y, while the second signal lines 140 extend along the second direction x. The second direction x is not parallel to the third direction y. For example, the second direction x is perpendicular to the third direction y.

In this embodiment, each of the first signal lines 120 is electrically connected to multiple first transistors T1 arranged along the second direction x, and each of the second signal lines 140 is electrically connected to multiple first transistors T1 arranged along the third direction y. In some embodiments, the first transistor T1 can serve as the read transistor in the memory cell MC1, and one of the first signal line 120 or the second signal line 140 can serve as the read bit line, while the other can serve as the read word line.

Each of the first transistors T1 is embedded in the top insulating layer 150, the spacer layer 130, the bottom insulating layer 110, a corresponding first signal line 120, and a corresponding second signal line 140. For example, each of the first transistors T1 includes a first semiconductor layer 160, a first gate insulating layer 170, and a first gate electrode 180. The first semiconductor layer 160, the first gate insulating layer 170, and the first gate electrode 180 extend through the first signal line 120 and the second signal line 140.

The first semiconductor layer 160 is electrically connected to the first signal line 120 and the second signal line 140. The first semiconductor layer 160 is in contact with the sidewalls of the top insulating layer 150, the spacer layer 130, the bottom insulating layer 110, the corresponding first signal line 120, and the corresponding second signal line 140. The first gate insulating layer 170 is disposed on the first semiconductor layer 160. The first gate electrode 180 is disposed on the first gate insulating layer 170 and extends along the first direction z. The first gate insulating layer 170 is disposed between the first gate electrode 180 and the first semiconductor layer 160.

In some embodiments, the first gate insulating layer 170 and the first semiconductor layer 160 laterally surround the first gate electrode 180. Specifically, a first layered structure LS1 comprising the first semiconductor layer 160 and the first gate insulating layer 170 is disposed on the first gate electrode 180, and the first layered structure LS1 covers the sidewalls 184a, 184b, 184c, 184d (e.g., four sidewalls shown in FIGS. 1B and 1C) and a bottom surface 182 of the first gate electrode 180. In other words, the first layered structure LS1 encircles the first gate electrode 180 in a x-y cross-sectional view, where the x-y cross-sectional view is parallel to the second direction x and the third direction y.

The first gate insulating layer 170 is positioned on the side of the first layered structure LS1 closest to the first gate electrode 180, while the first semiconductor layer 160 is positioned on the side of the first layered structure LS1 farthest from the first gate electrode 180. The first layered structure LS1 extend laterally to encircle the first gate electrode 180. In other words, the first layered structure LS1 surrounds sidewalls 184a, 184b, 184c, 184d of the first gate electrode 180, wherein the sidewalls 184a, 184b, 184c, 184d are located between the bottom surface 182 and the top surface 186 of the first gate electrode 180. In some embodiments, the first layered structure LS1 does not cover the top surface 186 of the first gate electrode 180. For example, the top surface 186 of the first gate electrode 180 is aligned with the top surface 176 of the first gate insulating layer 170 and the top surface 166 of the first semiconductor layer 160. In some embodiments, the thickness of the first semiconductor layer 160 is in a range from 1 nm to 20 nm. In some embodiments, the thickness of the first gate insulating layer 170 is in a range from 0.1 nm to 20 nm.

An insulating layer 210 is disposed over the first gate electrode 180 and between the first transistors T1 and the second transistors T2. The insulating layer 210 is in contact with the top surface 186 of the first gate electrodes 180, the top surface 166 of the first semiconductor layers 160, the top surface 176 of the first gate insulating layers 170, and the top insulating layer 150. Conductive vias 212 are embedded in the insulating layer 210. The conductive vias 212 are located over and in contact with the first gate electrodes 180.

A dielectric layer 220 is disposed above the insulating layer 210. First connection electrodes 230 are embedded in the dielectric layer 220 and are electrically connected with the conductive vias 212.

The MIM capacitors CA are located over the first connection electrodes 230. The connection electrodes 230 electrically connects the conductive vias 212 to the MIM capacitors CA. Each of the MIM capacitors CA includes a first electrode 320, a capacitor insulating layer 330, and a second electrode 340. In some embodiments, a dielectric layer 310 is disposed over the dielectric layer 220 and the first connection electrode 230. The first electrode 320 is disposed in a hole of the dielectric layer 310. The first electrode 320 extends from a top surface of the first connection electrode 230 to beyond a top surface of the dielectric layer 310. The dielectric layer 310 surrounds the first electrode 320 and contacts the top surface of the connection electrode 230 and a sidewall of the first electrode 320. The capacitor insulating layer 330 is disposed on the first electrode 320. The second electrode 340 is disposed on the capacitor insulating layer 330. The capacitor insulating layer 330 and the second electrode 340 covers sidewalls and a top surface of the first electrode 320 in the x-z cross-sectional view, where the x-z cross-sectional view is parallel to the second direction x and the first direction z.

By configuring the first electrode 320 to protrude upward from the first connection electrode 230, the contact area between the first electrode 320 and the capacitor insulating layer 330, as well as the contact area between the capacitor insulating layer 330 and the second electrode 340, can be increased. Consequently, the capacitance value of the MIM capacitor CA can be enhanced. In this embodiment, the first electrode 320 of each MIM capacitor CA includes one structure protruding upward from the first connection electrode 230. However, this disclosure is not limited thereto. In other embodiments, the first connection electrode 230 may have a flat structure, or the first electrode 320 may include multiple structures protruding upward from the first connection electrode 230. The first electrode 320 of the MIM capacitor CA is electrically connected to the first gate electrodes 180 through the first connection electrodes 230 and the conductive vias 212.

The second transistors T2 are located above the MIM capacitors CA. The second transistors T2 and the MIM capacitors CA are embedded in an interlayer dielectric layer 240 over the dielectric layer 220. Each of the MIM capacitor CA is disposed between and electrically connected to a corresponding one first transistor T1 and a corresponding one second transistor T2. The second electrode 340 of the MIM capacitor CA is electrically connected to the second transistor T2.

Each of the second transistors T2 includes a second semiconductor layer 250, a second gate insulating layer 260, and a second gate electrode 270. The second semiconductor layer 250, the second gate insulating layer 260, and the second gate electrode 270 extend perpendicular to the first direction z. For example, the second semiconductor layer 250, the second gate insulating layer 260, and the second gate electrode 270 extend along the third direction y. The MIM capacitor CA is disposed between the first gate electrode 180 and the second electrode 270 in the first direction z. The second electrode 340 of the MIM capacitor CA is electrically connected to the second semiconductor layer 250.

In some embodiments, the second gate insulating layer 260 and the second semiconductor layer 250 laterally surround the second gate electrode 270. Specifically, a second layered structure LS2 comprising the second semiconductor layer 250 and the second gate insulating layer 260 is disposed on the second gate electrode 270, and the second layered structure LS2 covers the sidewalls 274a, 274b, a bottom surface 272, and a top surface 276 of the second gate electrode 270. In other words, the second layered structure LS2 encircles the second gate electrode 270 in an x-z cross-sectional view.

The second gate insulating layer 260 is positioned on the side of the second layered structure LS2 closest to the second gate electrode 270, while the second semiconductor layer 250 is positioned on the side of the second layered structure LS2 farthest from the second gate electrode 270. The second layered structure LS2 extend longitudinally to encircle the second gate electrode 270. In other words, the second layered structure LS2 surrounds the sidewalls 274a, 274b, the bottom surface 272, and the top surface 276 of the second gate electrode 270, wherein the sidewalls 274a, 274b are positioned between the bottom surface 272 and the top surface 276 of the second gate electrode 270 in the first direction z. A portion of the second semiconductor layer 250 and a portion of the second gate insulating layer 260 are disposed between the first gate electrode 180 and the second gate electrode 270. In some embodiments, the thickness of the second gate insulating layer 260 is in a range from 0.1 nm to 20 nm. In some embodiments, the thickness of the second semiconductor material layer 250 is in a range from 1 nm to 20 nm.

A top dielectric layer 280 is disposed over the interlayer dielectric layer 240. A second connection electrode 290 is embedded in the top dielectric layer 280 and electrically connected to the second semiconductor layer 250. The second gate electrode 270, the second gate insulating layer 260, and the second semiconductor layer 250 are located between the MIM capacitor CA and the second connection electrode 290 in the first direction z. The second semiconductor layer 250 extends from the second electrode 340 of the MIM capacitor CA to the second connection electrode 290.

Third signals 300 are disposed over and electrically connected to the second connection electrode 290. In some embodiments, the second transistor T2 can serve as the write transistor in the memory cell MC1. The second gate electrodes 270 of multiple second transistors T2 arranged along the third direction y are connected together to form a write word line extending along the third direction y. Meanwhile, the third signals 300 extend along the second direction x and function as write bit lines.

Based on the above, by overlapping the first transistor T1, the MIM capacitor CA, and the second transistor T2 along the first direction z, the size of the memory cell MC1 can be reduced, thereby increasing the density of the memory cells MC1 in the memory device 10.

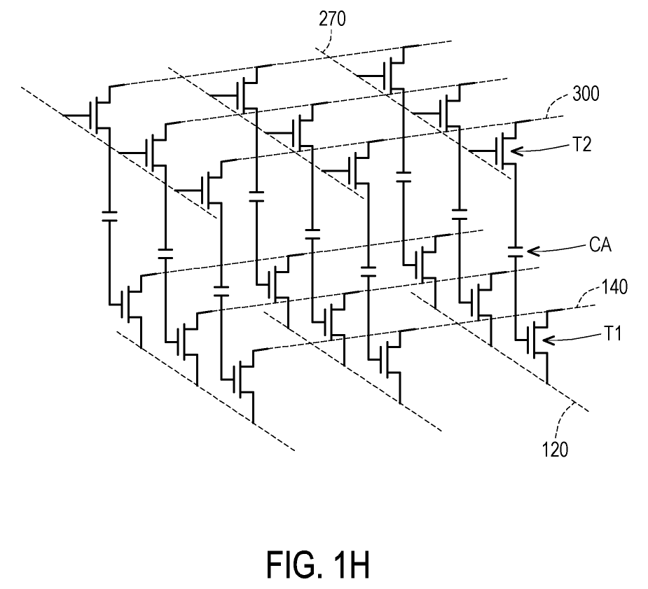

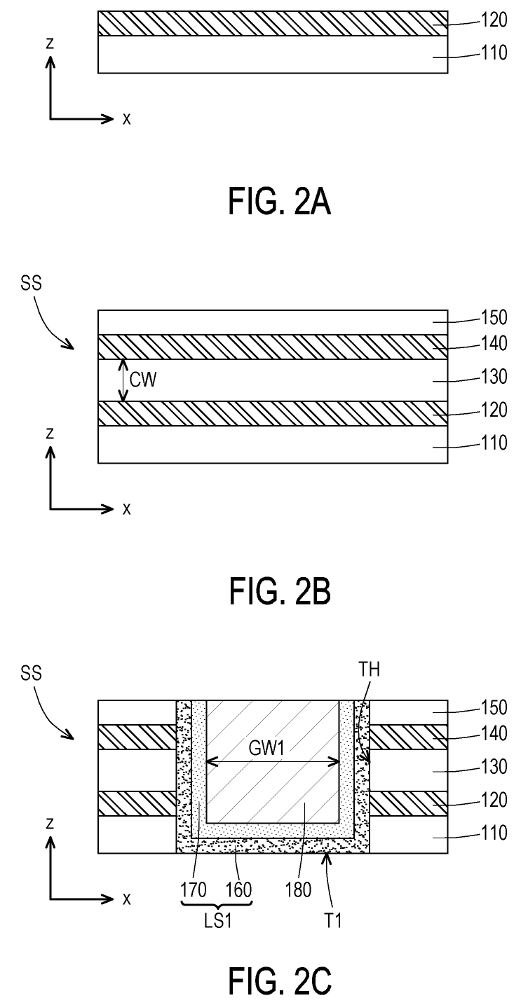

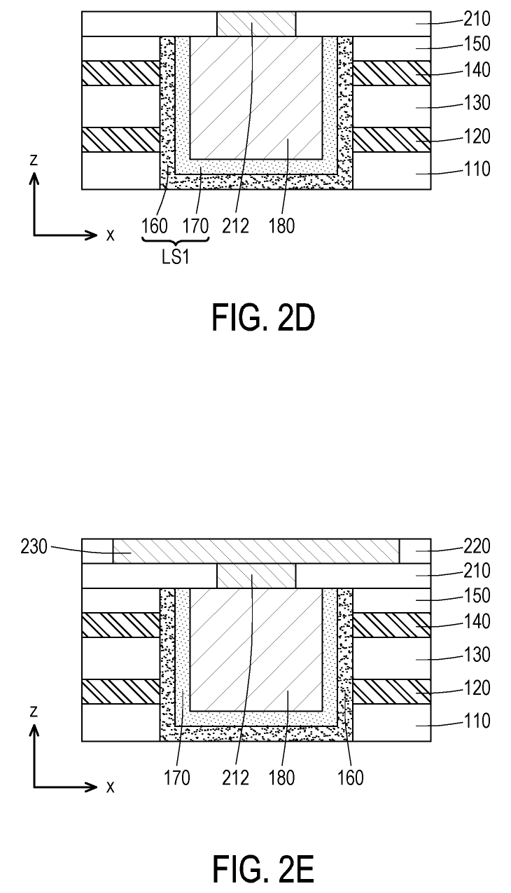

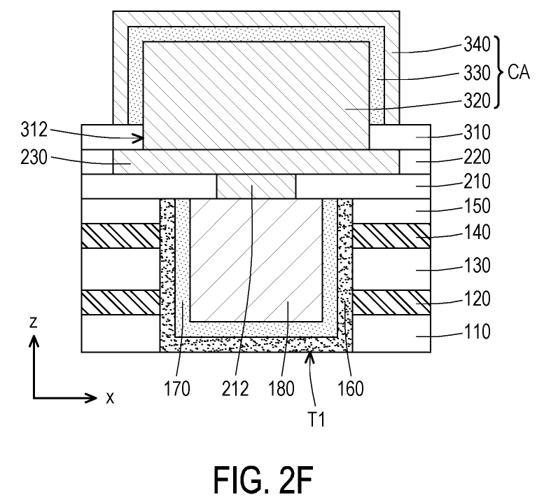

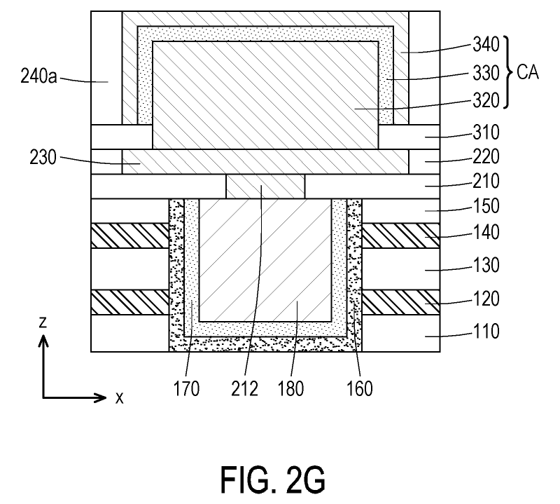

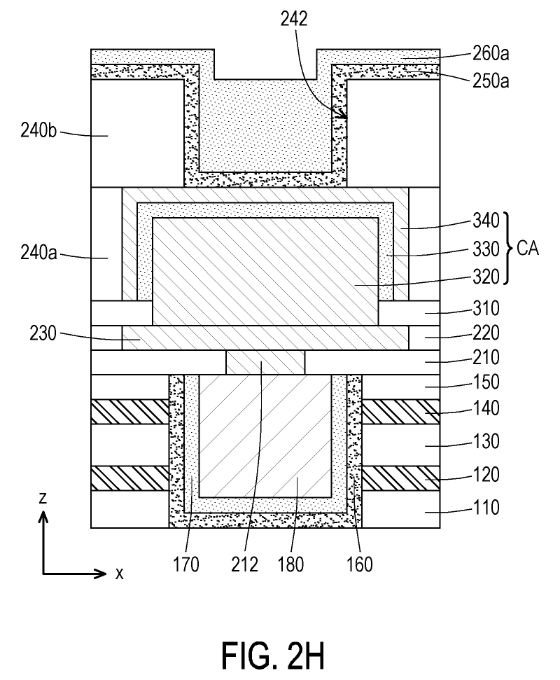

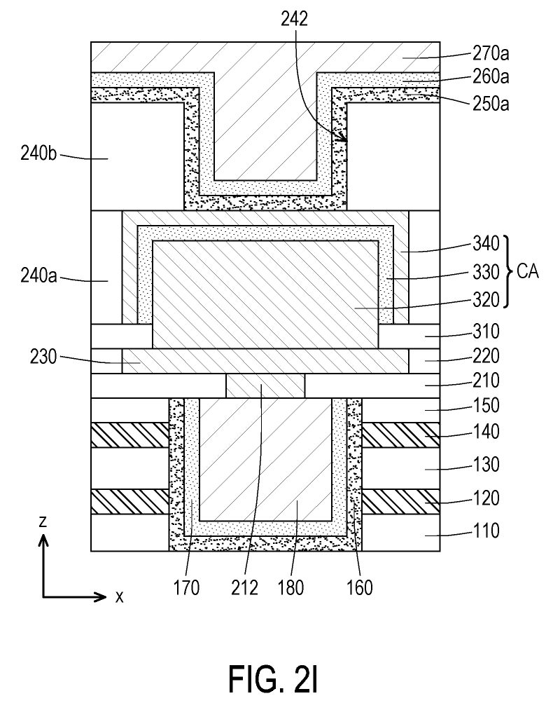

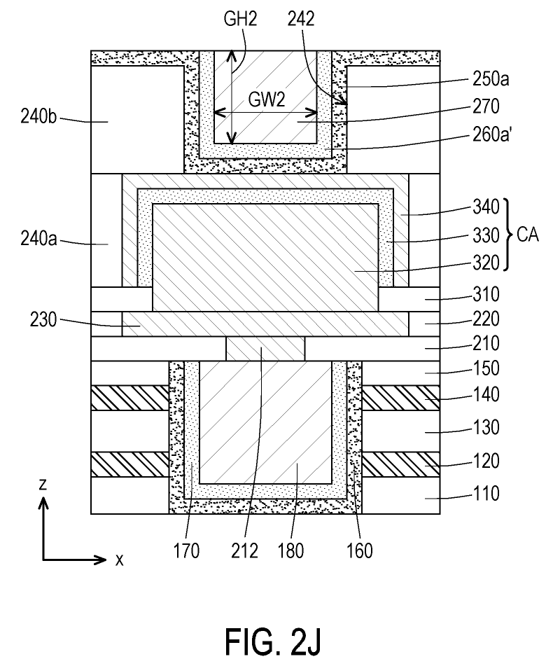

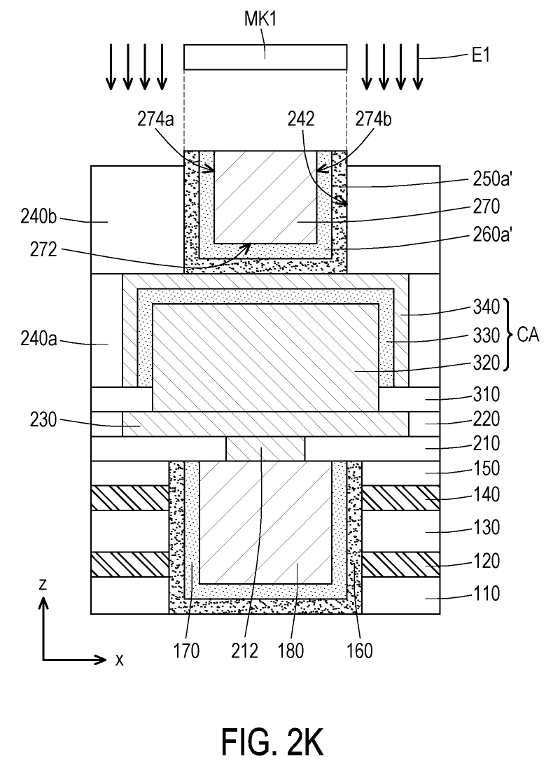

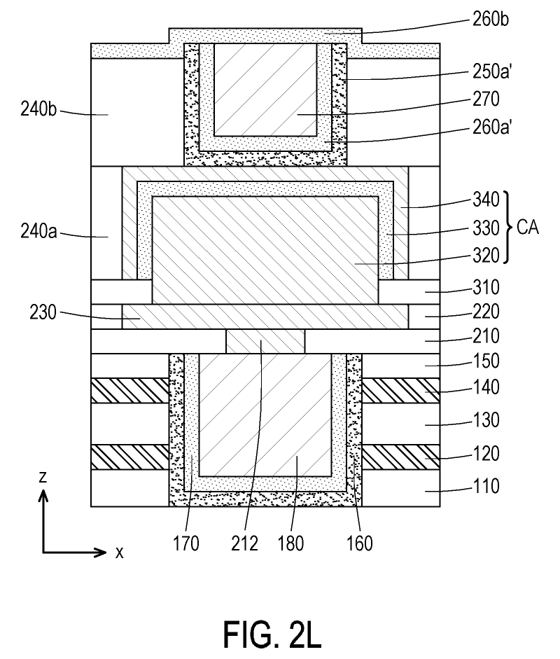

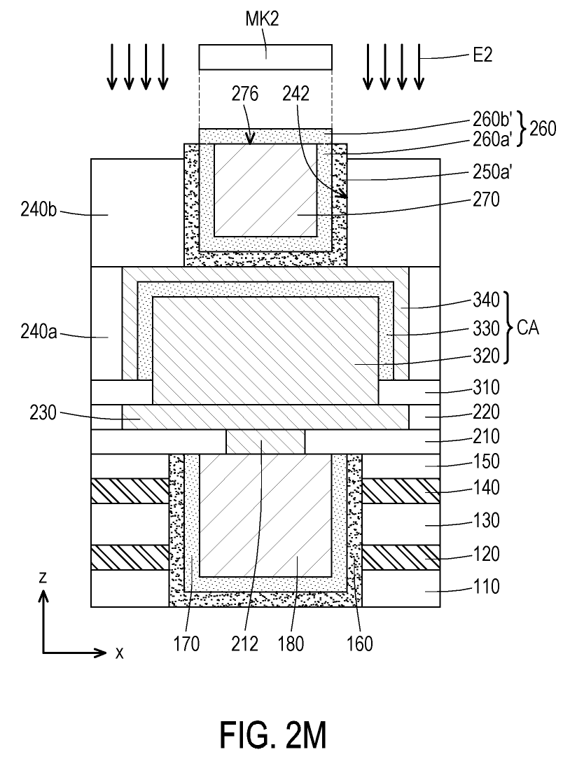

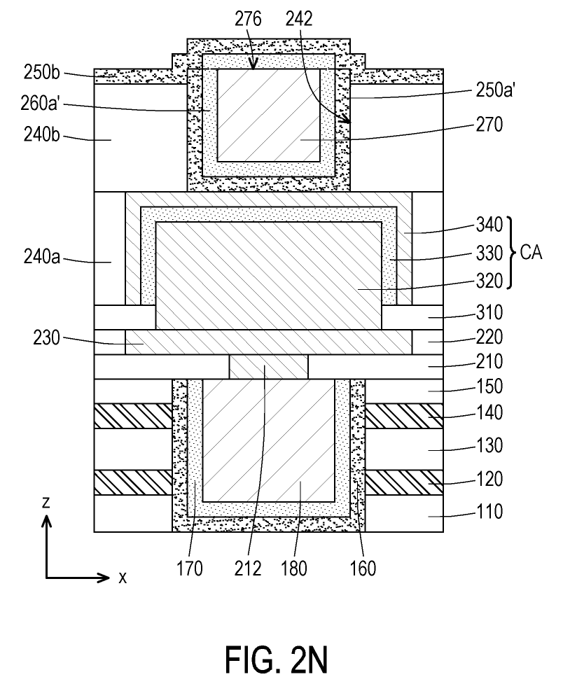

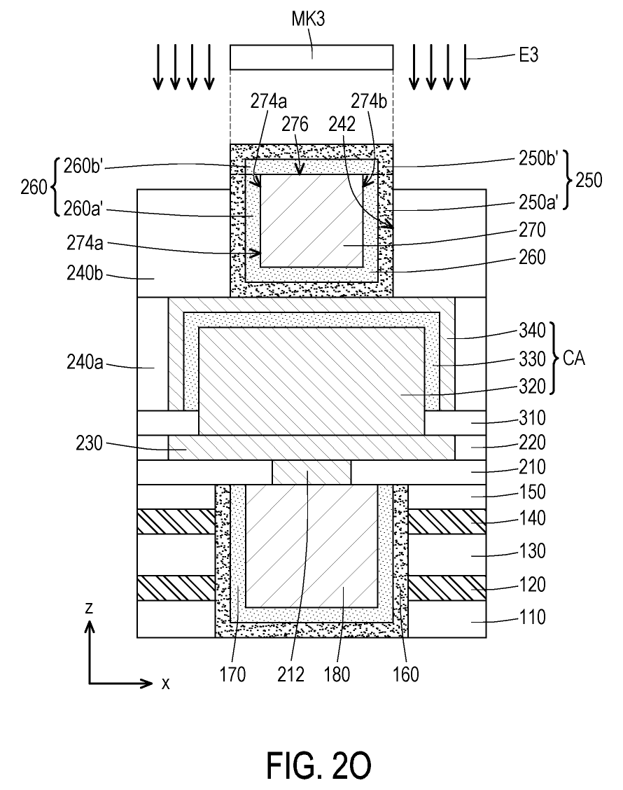

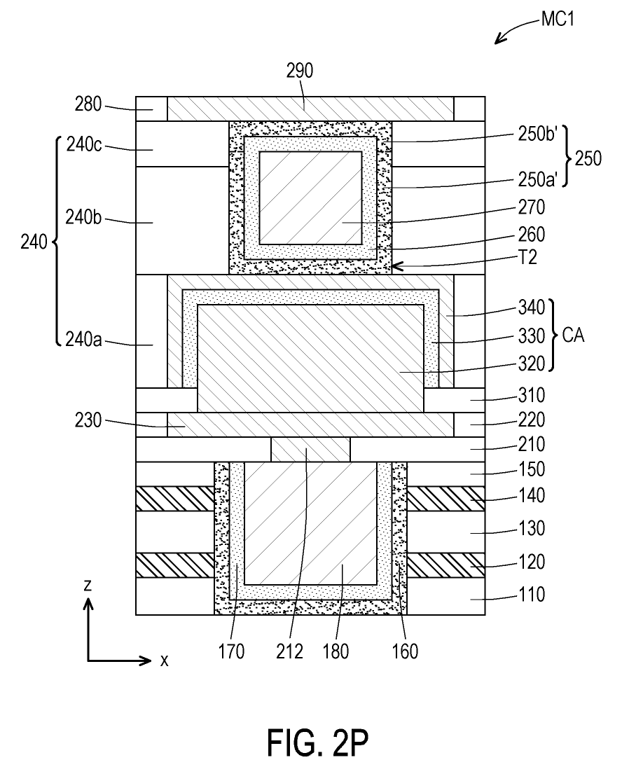

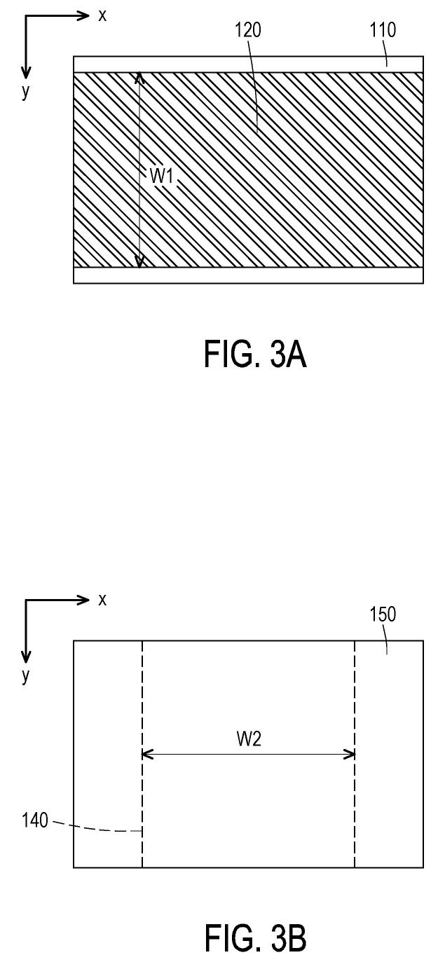

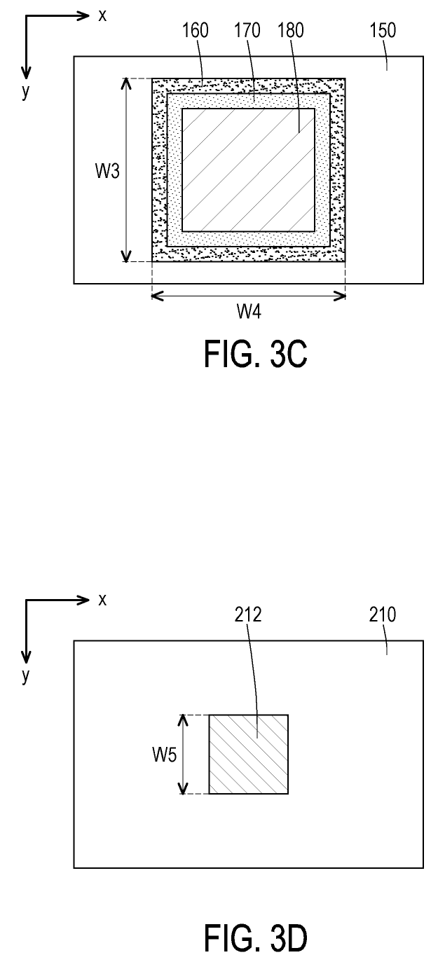

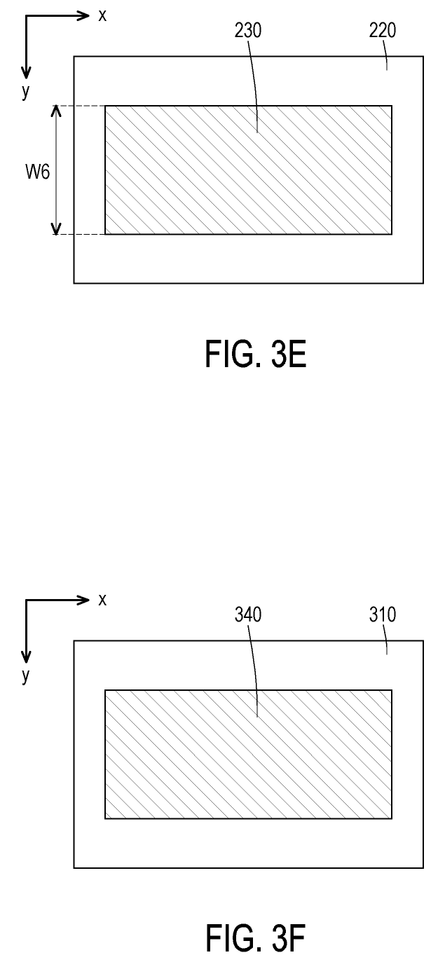

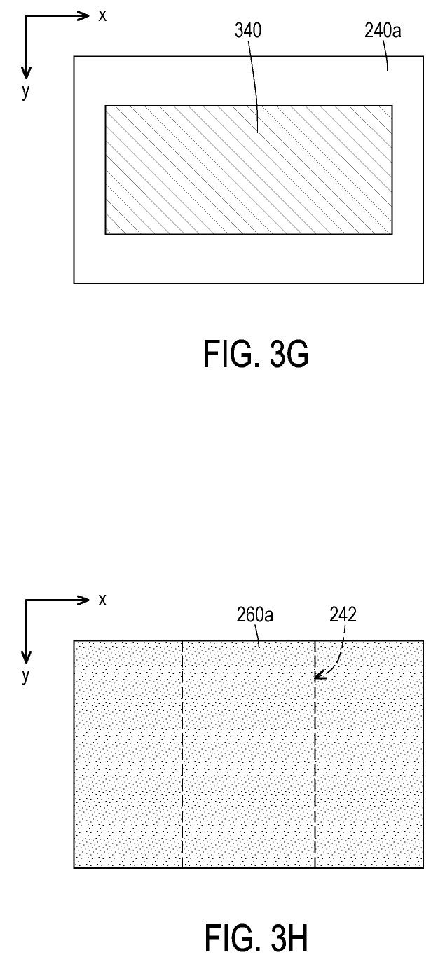

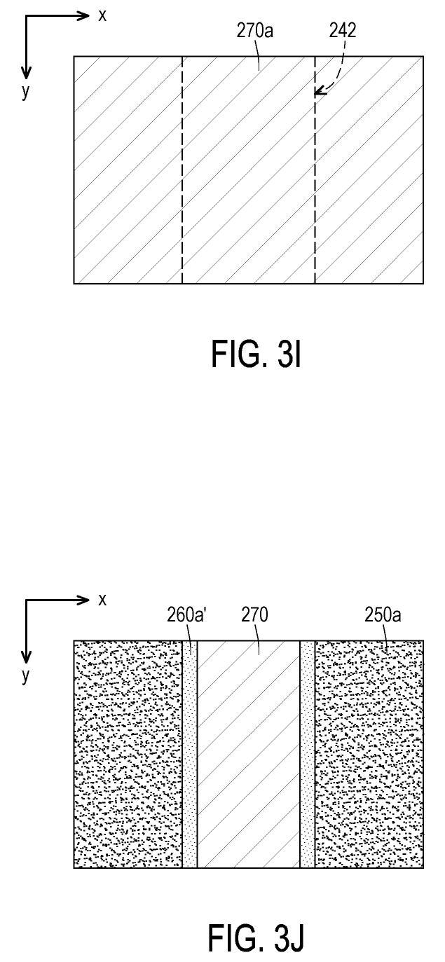

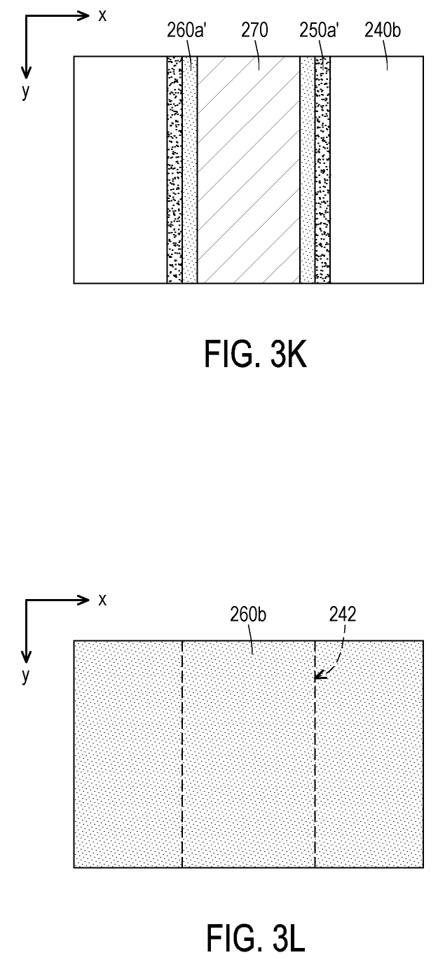

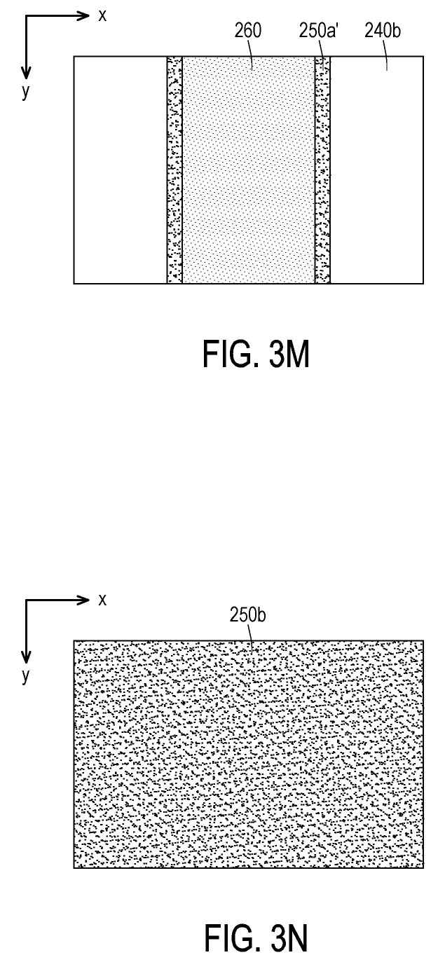

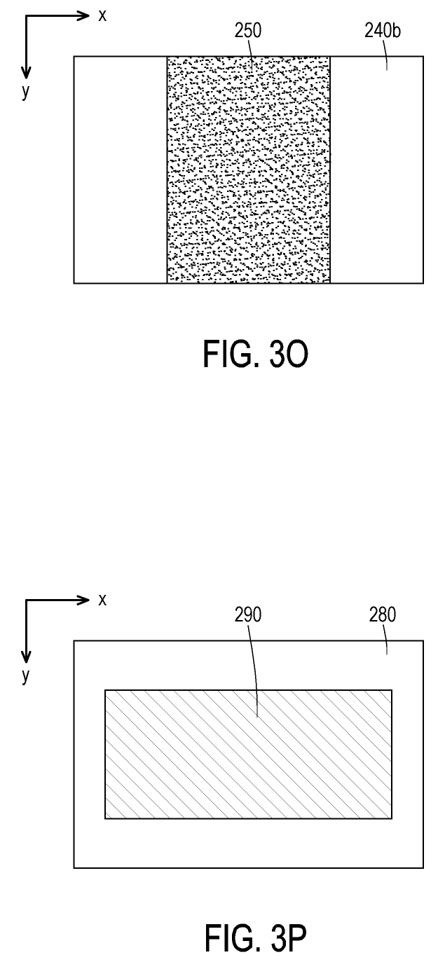

FIGS. 2A-2P illustrate cross-sectional views of various stages in a fabricating method for a memory cell MC1 according to some embodiments of the present disclosure. FIGS. 3A-3P illustrate perspective top views of various stages in a fabricating method for a memory cell MC1 according to some embodiments of the present disclosure. Referring to FIGS. 2A and 3A, the first signal line 120 is formed on the bottom insulating layer 110. In some embodiments, the material of the first signal line 120 includes metal (such as W, Ru, Cu, etc.), while the material of the bottom insulating layer 110 includes an oxide (such as SiOx, etc.) or the like. In some embodiments, a metal material layer is blanket-deposited on the bottom insulating layer 110, followed by patterning the metal material layer to form the first signal line 120. In some embodiments, the width W1 of the first signal line 120 in the third direction y is in a range from 10 nm to 5,000 nm.

Referring to FIGS. 2B and 3B, the spacer layer 130, the second signal line 140, and the top insulating layer 150 are sequentially formed over the first signal line 120. In some embodiments, the spacer layer 130 and the top insulating layer 150 have the same material as the bottom insulating layer 110 (such as SiOx, etc.), but the present disclosure is not limited to this. In some embodiments, the second signal line 140 is made of metal (such as W, Ru, Cu, etc.) and is formed using the same method as the first signal line 120, but the present disclosure is not limited to this. In some embodiments, the width W2 of the second signal line 140 in the second direction x is in a range from 10 nm to 5,000 nm.

In some embodiments, the thickness CW of the spacer layer 130 is in a range from 0.1 nm to 100 nm. In certain embodiments, the thickness of the spacer layer 130 can be regarded as the channel length of the first transistor.

A stack structure SS includes the bottom insulating layer 110, the first signal line 120, the spacer layer 130, the second signal line 140, and the top insulating layer 150 sequentially stacked along the first direction z.

Referring to FIGS. 2C and 3C, a through hole TH is formed through the top insulating layer 150, the second signal line 140, the spacer layer 130, and the first signal line 120 using an etching process (such as wet etching or dry etching). In some embodiments, the through hole TH extends through the first signal line 120 and into the bottom insulating layer 110 beneath the first signal line 120. In other words, the through hole TH is formed through the stack structure SS.

In FIG. 2C, at the location of the through hole TH, the sidewalls of the top insulating layer 150, the second signal line 140, the spacer layer 130, the first signal line 120, and the bottom insulating layer 110 are aligned, but the present disclosure is not limited to this. In some embodiments, due to differences in etching rates of different materials, the through hole TH may have uneven sidewalls.

The first transistor T1 including the first semiconductor layer 160, the first gate insulating layer 170, and the first gate electrode 180 is formed in the through hole TH.

The first semiconductor layer 160 is formed in the through hole TH. For example, a semiconductor material layer is first deposited into the through hole TH and on the top surface of the insulating layer 150. The excess portion of the semiconductor material layer is then removed to form the first semiconductor layer 160. Methods for removing the excess portion of the semiconductor material layer include chemical-mechanical polishing (CMP) process, etching process, or other similar processes. In some embodiments, the first semiconductor layer 160 includes in-situ Si, oxide semiconductor, or other similar materials. In some embodiments, the first semiconductor layer 160 is deposited using processes such as atomic layer deposition (ALD) process, chemical vapor deposition (CVD) process, physical vapor deposition (PVD) process, or other suitable methods. In some embodiments, the first semiconductor layer 160 with the intended doping concentration is directly formed in the deposition process, meaning there is no need for an additional doping process for the first semiconductor layer 160. In other words, a junction-less transistor may be formed.

The first gate insulating layer 170 is formed on the first semiconductor layer 160 in the through hole TH. For example, an insulating material layer is first deposited into the through hole TH and on the first semiconductor layer 160 (or the semiconductor material layer). The excess portion of the insulating material layer is then removed to form the first gate insulating layer 170. Methods for removing the excess portion of the insulating material layer include CMP process, etching process, or other similar processes. In some embodiments, the first gate insulating layer 170 includes a high-k dielectric material, such as HfOx, AlOx, SiOx, or the like. In some embodiments, the first gate insulating layer 170 is deposited using processes such as ALD process, CVD process, PVD process, or other suitable methods.

The first gate electrode 180 is formed on the first gate insulating layer 170 in the through hole TH. For example, a metal material layer is first deposited into the through hole TH and on the first gate insulating layer 170 (or the insulating material layer). The excess portion of the metal material layer is then removed to form the first gate electrode 180. Methods for removing the excess portion of the metal material layer include CMP process, etching process, or other similar processes. In some embodiments, the first gate electrode 180 includes metal, such as W, TiN, Ru, or the like. In some embodiments, the first gate electrode 180 is deposited using processes such as ALD, CVD, PVD, electroplating, electroless plating, or other suitable methods. In the present embodiment, the first gate electrode 180 has a single-layer structure; however, the present disclosure is not limited thereto. In other embodiments, the first gate electrode 180 may have a multi-layer structure.

In some embodiments, by a surface planarization (e.g., CMP) process, the top surfaces of the top insulating layer 150, the first semiconductor layer 160, the first gate insulating layer 170, and the first gate electrode 180 are aligned. The first layered structure LS1, composed of the first gate insulating layer 170 and the first semiconductor layer 160, covers the bottom surface and side surfaces of the first gate electrode 180, while exposing the top surface of the first gate electrode 180.

In some embodiments, the width W3 of the first semiconductor layer 160 in the third direction y is in a range from 10 nm to 5,000 nm. In some embodiments, the width W3 is less than or equal to the width W1 of the first signal line 120 in the third direction y (refer to FIG. 3A). When the width W3 is smaller than W1, the first signal line 120 may surround the first semiconductor layer 160.

In some embodiments, the width W4 of the first semiconductor layer 160 in the second direction x is in a range from 10 nm to 5,000 nm. In some embodiments, the width W4 is less than or equal to the width W2 of the second signal line 140 in the second direction x (refer to FIG. 3B). When the width W4 is smaller than W2, the second signal line 140 may surround the first semiconductor layer 160.

In some embodiments, a width GW1 of the first gate electrode 180 is in a range from 0.1 nm to 100 nm.

Referring to FIGS. 2D and 3D, the insulating layer 210 and the conductive via 212 are formed over the first gate electrode 180. For example, an insulating material layer is first formed over the first gate electrode 180, the first layered structure LS1, and the top insulating layer 150. Subsequently, the insulating material layer is etched to create an opening exposing the first gate electrode 180. Finally, the opening is filled with a conductive material to form the conductive via 212 embedded in the insulating layer 210. In some embodiments, forming the conductive via 212 includes forming a conductive material layer over the insulating layer 210 and within the opening of the insulating layer 210 by ALD, CVD, PVD, electroplating, electroless plating, or other suitable methods. Thereafter, a CMP process is employed to remove portions of the conductive material layer extending beyond the insulating layer 210, leaving the conductive via 212 over the first gate electrode 180.

In some embodiments, the material of the insulating layer 210 includes, for example, SiOx, AlOx, SiN, or other suitable insulating materials. In some embodiments, the material of the conductive via 212 includes, for example, W, Ru, Cu, or other suitable metal materials.

In some embodiments, a width W5 of the conductive via 212 in the third direction y is in a range from 10 nm to 5,000 nm. In some embodiments, a width of the conductive via 212 in the second direction x is also in a range from 10 nm to 5,000 nm.

Referring to FIGS. 2E and 3E, the first connection electrode 230 is formed over the conductive via 212 and the first gate electrode 180. For example, the dielectric layer 220 is first formed over the insulating layer 210. The dielectric layer 220 includes an opening exposing the conductive via 212. Subsequently, the opening is filled with a conductive material to form the first connection electrode 230. In some embodiments, after filling the opening with the conductive material, a CMP process is performed to remove the portion of the conductive material exceeding the opening, such that the top surface of the first connection electrode 230 aligns with the top surface of the dielectric layer 220.

In some embodiments, the material of the dielectric layer 220 includes oxides (such as SiOx), or other insulating materials. In some embodiments, the dielectric layer 220 has a single-layer or multilayer structure. In some embodiments, the material of the first connection electrode 230 includes W, Ru, Cu, or other metal materials.

In some embodiments, a width W6 of the first connection electrode 230 in the third direction y is in a range from 10 nm to 5,000 nm. In some embodiments, a width of the first connection electrode 230 in the second direction x is also in a range from 10 nm to 5,000 nm.

Referring to FIGS. 2F and 3F, the MIM capacitor CA is formed over the first transistor T1 and the first connection electrode 230. For example, a dielectric layer 310 with a hole 312 is formed over the dielectric layer 220. The hole 312 of the dielectric layer 310 overlaps the first connection electrode 230. In some embodiments, the material of the dielectric layer 310 includes SiOx, AlOx, SiN, or similar materials.

Next, the first electrode 320 is formed within the hole 312 of the dielectric layer 310. The first electrode 320 extends from the top surface of the first connection electrode 230 to beyond the top surface of the dielectric layer 310. For instance, a conductive material is deposited within the hole 312 and on the top surface of the dielectric layer 310 through ALD, CVD, PVD, electroplating, electroless plating, or other suitable methods. The deposited conductive material is then patterned to form the first electrode 320 protruding from the dielectric layer 310.

Subsequently, the capacitor insulating layer 330 is formed over the first electrode 320. The capacitor insulating layer 330 covers both the top surface and the sidewalls of the first electrode 320. In some embodiments, the capacitor insulating layer 330 is in contact with the top surface of the dielectric layer 310. Finally, the second electrode 340 is formed on the capacitor insulating layer 330. The capacitor insulating layer 330 and the second electrode 340 are shaped along the protruding first electrode 320 to complete the MIM capacitor CA.

In some embodiments, the materials of the first electrode 320 and the second electrode 340 include W, Ru, Cu, or other conductive materials, while the material of the capacitor insulating layer 330 includes HfOx, AlOx, SiOx, or other high-dielectric-constant materials. In some embodiments, the thickness of the capacitor insulating layer 330 is in a range between 0.1 nm to 20 nm.

Referring to FIGS. 2G and 3G, a protection layer 240a is formed on the dielectric layer 310. The protection layer 240a laterally surrounds the MIM capacitor CA while exposing the second electrode 340 of the MIM capacitor CA. In FIG. 2G, the protection layer 240a is depicted as a single-layer structure; however, the present disclosure is not limited thereto. In other embodiments, the protection layer 240a may have a multilayer structure. In some embodiments, the material of the protection layer 240a includes oxides (such as SiOx) or other insulating materials.

Referring to FIGS. 2H and 3H, a first dielectric layer 240b with an opening 242 is formed over the MIM capacitor CA. The opening 242 overlaps with the second electrode 340 in the first direction z. The opening 242 is extending perpendicular to the first direction z. For example, the opening 242 is extending along the third direction y.

In FIG. 2H, the first dielectric layer 240b is depicted as a single-layer structure; however, the present disclosure is not limited thereto. In other embodiments, the first dielectric layer 240a may have a multilayer structure. In some embodiments, the material of the first dielectric layer 240a includes oxides (such as SiOx) or other insulating materials.

A first semiconductor material layer 250a is formed in the opening 242. For example, the first semiconductor material layer 250a is conformally deposited within the opening 242 and over the top surface of the first dielectric layer 240b.

In some embodiments, the first semiconductor material layer 250a includes in-situ Si, oxide semiconductor, or other similar materials. In some embodiments, the first semiconductor material layer 250a is deposited using processes such as ALD process, CVD process, PVD process, or other suitable methods.

A first gate insulating material layer 260a is formed on the first semiconductor material layer 250a within the opening 242. In some embodiments, the first gate insulating material layer 260a is not only located on the first semiconductor material layer 250a within the opening 242 but is also formed over the portion of the first semiconductor material layer 250a outside the opening 242.

In some embodiments, the first gate insulating material layer 260a includes a high-k dielectric material, such as HfOx, AlOx, SiOx, or the like. In some embodiments, the first gate insulating material layer 260a is deposited using processes such as ALD process, CVD process, PVD process, or other suitable methods

Referring to FIGS. 2I and 3I, a gate material layer 270a is formed on the first gate insulating material layer 260a in the opening 242. In some embodiments, the gate material layer 270a is not only located on the first gate insulating material layer 260a within the opening 242 but is also formed over the portion of the first gate insulating material layer 260a outside the opening 242.

In some embodiments, due to the narrow width of the opening 242 in the second direction x, the first gate insulating material layer 260a formed on the sidewalls of the opening 242 may fill most or all of the remaining space within the opening 242. Therefore, before forming the gate material layer 270a, the first gate insulating material layer 260a is etched to ensure sufficient space in the opening 242 to accommodate the gate material layer 270a. For example, the first gate insulating material layer 260a within the opening 242 is etched to remove a portion of the layer within the opening 242. By controlling the etching process, the first gate insulating material layer 260a inside the opening 242 is not completely removed, thus preventing the subsequently formed gate material layer 270a from contacting the first semiconductor material layer 250a within the opening 242. In some embodiments, prior to the etching process, a mask (e.g., photoresist or other similar structures) may optionally be formed over the first gate insulating material layer 260a.

In other embodiments, if the width of the opening 242 in the second direction x is sufficiently large, there is enough space in the opening 242 to accommodate the gate material layer 270a even after depositing the first gate insulating material layer 260a. In such cases, the aforementioned etching process for the first gate insulating material layer 260a can be omitted.

In some embodiments, the gate material layer 270a includes metal, such as W, TiN, Ru, or the like. In some embodiments, the gate material layer 270a is deposited using processes such as ALD, CVD, PVD, electroplating, electroless plating, or other suitable methods. In the present embodiment, the gate material layer 270a has a single-layer structure; however, the present disclosure is not limited thereto. In other embodiments, the gate material layer 270a may have a multi-layer structure.

Referring to FIGS. 2J and 3J, a portion of the gate material layer 270a outside the opening 242 is removed, with a remaining portion of the gate material layer 270a forming the second gate electrode 270. A portion of the first gate insulating material layer 260a outside the opening 242 is removed, with a remaining portion of the first gate insulating material layer 260a forming a first portion 260a’ of the second gate insulating layer. The second gate electrode 270 is at least partially located in the opening 242.

In some embodiments, the method of removing the portion of the gate material layer 270a and the portion of the first gate insulating material layer 260a includes one or more CMP processes, etching processes, or other suitable methods.

In some embodiments, a width GW2 of the second gate electrode 270 is in a range from 0.1 nm to 100 nm, and a height GH2 of the second gate electrode 270 is in a range from 0.1 nm to 100 nm.

Referring to FIGS. 2K and 3K, a portion of the first semiconductor material layer 250a outside the opening 242 is removed to form a first portion 250a’ of the second semiconductor layer. For example, using the mask MK1, an etching process E1 is performed on the first semiconductor material layer 250a to remove the portion of the first semiconductor material layer 250a on the top surface of the first dielectric layer 240b. The etching process E1 may be a dry etching process or a wet etching process.

The first portion 260a’ of the second gate insulating layer and the first portion 250a’ of the second semiconductor layer extend from a position adjacent to a first side (e.g. the sidewalls 274a) of the second gate electrode 270, passes beneath a bottom surface 272 of the second gate electrode 270, and continues beyond a second side (e.g. the sidewalls 274b) of the second gate electrode 270.

The width of mask MK1 is approximately the same as the width of the opening 242. In some embodiments, the first portion 250a’, the first portion 260a’, and the second gate electrode 270 protrude from the top surface of the first dielectric layer 240b. In some embodiments, the mask MK1 can be formed directly on the second gate electrode 270 or spaced apart from it.

In some embodiments, the process of removing the portion of the gate material layer 270a and the portion of the first gate insulating material layer 260a, as shown in FIGS. 2J and 3J, can also be carried out using the mask MK1.

Referring to FIGS. 2L and 3L, a second gate insulating material layer 260b is formed on the second gate electrode 270, the first portion 260a’ of the second gate insulating layer, the first portion 250a’ of the second semiconductor layer and the top surface of the first dielectric layer 240b.

In some embodiments, the second gate insulating material layer 260b includes a high-k dielectric material, such as HfOx, AlOx, SiOx, or the like. In some embodiments, the second gate insulating material layer 260b and the first portion 260a’ include the same material.

In some embodiments, the second gate insulating material layer 260b is deposited using processes such as ALD process, CVD process, PVD process, or other suitable methods.

Referring to FIGS. 2M and 3M, the second gate insulating material layer 260b is patterned to form the second portion 260b’ of the second gate insulating layer 260 on the top surface 276 of the second gate electrode 270. The first portion 260a’ is connected to the second portion 260b’, such that the second gate insulating layer 260 surrounds the second gate electrode 270. The second gate insulating layer 260 is partially located in the opening 242.

For example, using the mask MK2, an etching process E2 is performed on the second gate insulating material layer 260b to remove the portion of the second gate insulating material layer 260b on the top surfaces of the first dielectric layer 240b and the first portion 250a’. The etching process E2 may be a dry etching process or a wet etching process. In some embodiments, the mask MK2 has a width smaller than the width of the opening 242, such that the first portion 250a’ of the second semiconductor layer is exposed after the etching process. In some embodiments, the mask MK2 can be formed directly on the second gate insulating material layer 260b or spaced apart from it.

Referring to FIGS. 2N and 3N, a second semiconductor material layer 250b is formed on the second gate insulating layer 260, the first portion 250a’ of the second semiconductor layer, and the top surface of the first dielectric layer 240b.

In some embodiments, the second semiconductor material layer 250b includes in-situ Si, oxide semiconductor, or other similar materials. In some embodiments, the second semiconductor material layer 250b and the first portion 250a’ include the same material.

In some embodiments, the second semiconductor material layer 250b is deposited using processes such as ALD process, CVD process, PVD process, or other suitable methods.

Referring to FIGS. 2O and 3P, the second semiconductor material layer 250b is patterned to form the second portion 250b’ of the second semiconductor layer 250 on the second gate insulating layer 260. The second portion 260b’ of the second gate insulating layer 260 and the second portion 250b’ of the second semiconductor layer 250 extends from the position adjacent to the first side (e.g. the sidewalls 274a) of the second gate electrode 270, passes over the top surface 276 of the second gate electrode 270, and continues beyond the second side (the sidewalls 274b) of the second gate electrode 270. The first portion 250a’ is connected to the second portion 250b’, such that the second semiconductor layer 250 surrounds the second gate electrode 270 and the second gate insulating layer 260. The second semiconductor layer 250 is partially located in the opening 242.

A portion of the second semiconductor material layer 250b on the first dielectric layer 240b is removed to form the second portion 250b’ of the second semiconductor layer 250. For example, using the mask MK3, an etching process E3 is performed on the second semiconductor material layer 250b to remove the portion of the second semiconductor material layer 250b. The etching process E3 may be a dry etching process or a wet etching process. The width of mask MK3 is approximately the same as the width of the opening 242. In some embodiments, the mask MK3 can be formed directly on the second semiconductor material layer 250b or spaced apart from it.

In some embodiments, the second semiconductor layer 250 achieves the desired doping concentration during the deposition process (i.e., when depositing the first semiconductor material layer 250a and the second semiconductor material layer 250b). This eliminates the need for an additional doping process for the second semiconductor layer 250. In other words, a junction-less transistor may be realized.

Referring to FIGS. 2P and 3P, a second dielectric layer 240c is formed on the first dielectric layer 240b to fill the gap between the top surface of the second semiconductor layer 250 and the top surface of the first dielectric layer 240b. The first dielectric layer 240b and the second dielectric layer 240c may include the same or different materials. In some embodiments, the interlayer dielectric layer 240 includes the second dielectric layer 240c, the first dielectric layer 240b, and the protection layer 240a. However, this disclosure is not limited thereto. In other embodiments, the interlayer dielectric layer 240 may have a single-layer structure or a structure with two or more layers.

In the present embodiment, a top dielectric layer 280 is formed over the interlayer dielectric layer 240, and the second connection electrode 290 is embedded within the top dielectric layer 280. In other embodiments, the top dielectric layer 280 and the second dielectric layer 240c can be considered as a single entity. In other words, an insulating material is deposited over the first dielectric layer 240b, completely covering the second semiconductor layer 250. The portion of the insulating material above the top surface of the second semiconductor layer 250 is regarded as the top dielectric layer 280, while the portion below the top surface of the second semiconductor layer 250 is regarded as the second dielectric layer 240c. In some embodiments, after depositing the insulating material, a CMP process is performed to planarize the material, followed by an etching process to create an opening exposing the second dielectric layer 240c. Finally, the second connection electrode 290 is formed within the opening.

In some embodiments, the material of the second dielectric layer 240c and the top dielectric layer 280 includes oxides (e.g., SiOx) or other insulating materials, while the material of the second connection electrode 290 includes W, Ru, Cu, or other metallic materials.

Based on the above, the resulting memory cell MC1 includes the first transistor T1, the MIM capacitor CA and the second transistor T2 stacked in the first direction z.

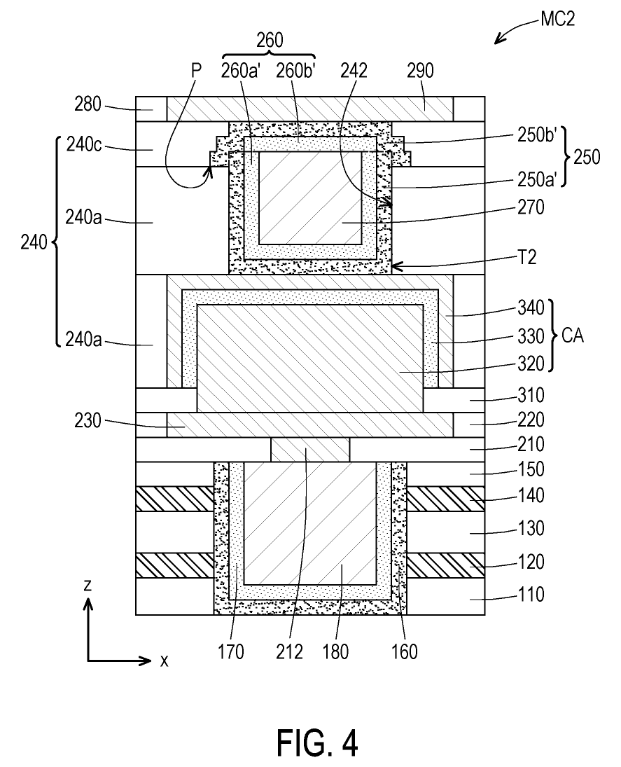

FIG. 4 illustrates a cross-sectional view of a memory cell MC2 according to some embodiments of the present disclosure. The components and some details in FIG. 4 follow those of the embodiments shown in FIGS. 2A-3P, where the same or similar reference numerals are used to denote the same or similar components. The technical content shared with the previous embodiments is omitted for brevity, and the omitted descriptions can be referenced from the earlier embodiments.

The difference between the memory cell MC2 in FIG. 4 and the memory cell MC1 in FIG. 2P lies in that, in the memory cell MC2 shown in FIG. 4, at least one end of the second portion 250b’ forms at least one protrusion P located on at least one side of the second semiconductor layer 250. For example, during the patterning process of the second semiconductor material layer 250b (refer to the steps shown in FIGS. 2O and 3O), if the mask MK3 is misaligned or too wide, the resulting second portion 250b’ may exhibit a misalignment or a width larger than the opening 242. In such cases, the sidewalls of the second semiconductor layer 250 may include protrusion P formed by the endpoints of the second portion 250b’.

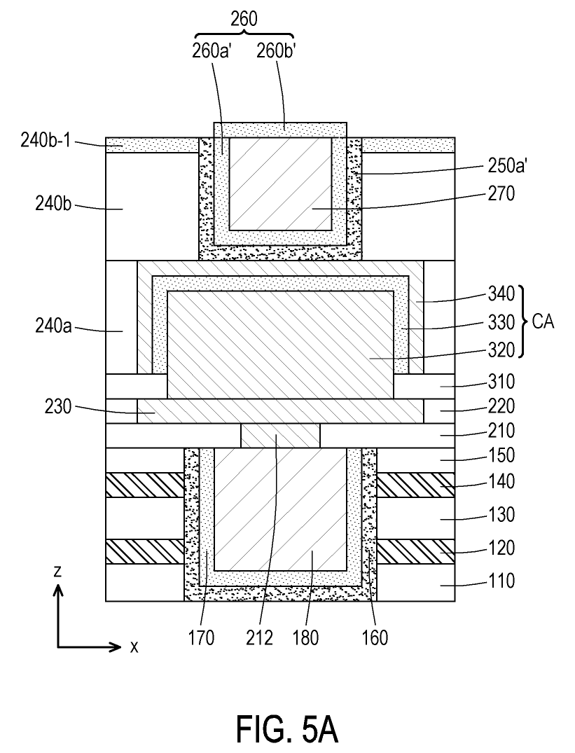

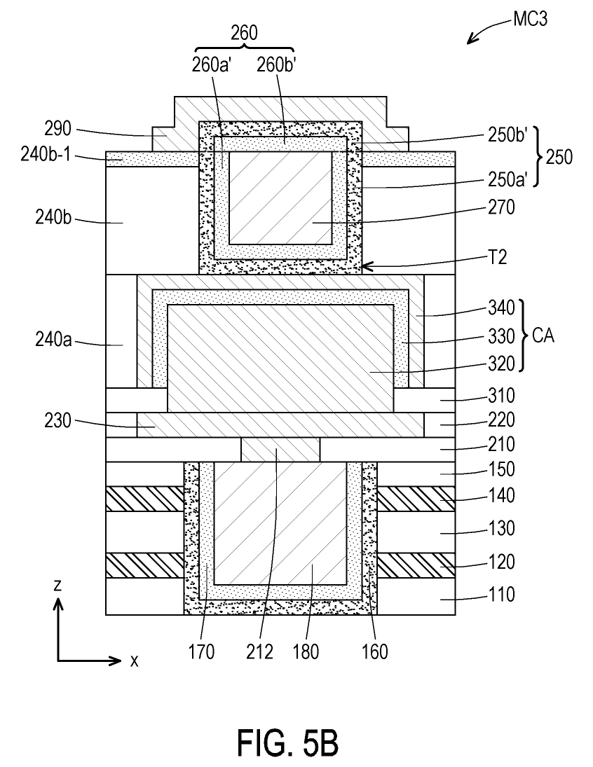

FIGS. 5A and 5B illustrate cross-sectional views of various stages in a fabricating method for a memory cell MC3 according to some embodiments of the present disclosure. The components and some details in FIGS. 5A and 5B follow those of the embodiments shown in FIGS. 2A-3P, where the same or similar reference numerals are used to denote the same or similar components. The technical content shared with the previous embodiments is omitted for brevity, and the omitted descriptions can be referenced from the earlier embodiments.

Referring to FIG. 5A, after the formation of the second gate insulating material layer 260b as shown in FIG. 2L, a patterning process is performed on the second gate insulating material layer 260b to expose the first portion 250a’ of the second semiconductor layer located beneath it. In this embodiment, the second gate insulating material layer 260b, after being patterned, includes the second dielectric layer 240b-1 located on the first dielectric layer 240b and the second portion 260b’ located on the second gate electrode 270. The second portion 260b’ connects to the first portion 260a’ and forms the second gate insulating layer 260 surrounding the second gate electrode 270.

Referring next to FIG. 5B, the second portion 250b’ is formed on the second portion 260b’. The second portion 250b’ connects to the first portion 250a’ through the space between the second dielectric layer 240b-1 and the second portion 260b’, thereby forming the second semiconductor layer 250 that surrounds both the second gate electrode 270 and the second gate insulating layer 260. The method for forming the second portion 250b’ can refer to the description related to FIGS. 2N-2O.

Finally, the second connection electrode 290 is formed on the second semiconductor layer 250. In some embodiments, before forming the second connection electrode 290, the top dielectric layer 280 may be formed on the second dielectric layer 240b-1 (refer to FIG. 2P).

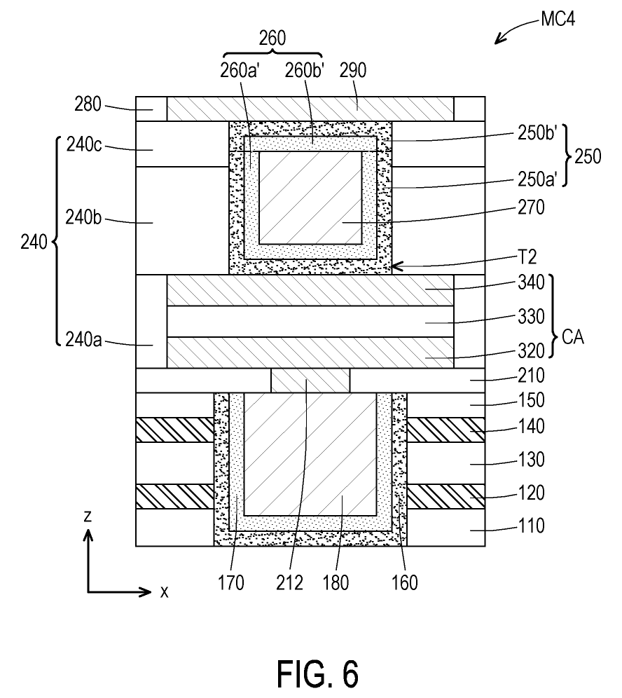

FIG. 6 illustrates a cross-sectional view of a memory cell MC4 according to some embodiments of the present disclosure. The components and some details in FIG. 6 follow those of the embodiments shown in FIGS. 2A-3P, where the same or similar reference numerals are used to denote the same or similar components. The technical content shared with the previous embodiments is omitted for brevity, and the omitted descriptions can be referenced from the earlier embodiments.

The difference between the memory cell MC4 in FIG. 6 and the memory cell MC1 in FIG. 2P lies in that the MIM capacitor CA in the memory cell MC4 shown in FIG. 6 is a planar capacitor. Specifically, the first electrode 320, the capacitor insulating layer 330, and the second electrode 340 all have flat structures in FIG. 6. In this embodiment, the first electrode 320 is directly formed on the conductive via 212. However, this disclosure is not limited thereto. In other embodiments, additional conductive structure(s) may be included between the first electrode 320 and the conductive via 212.

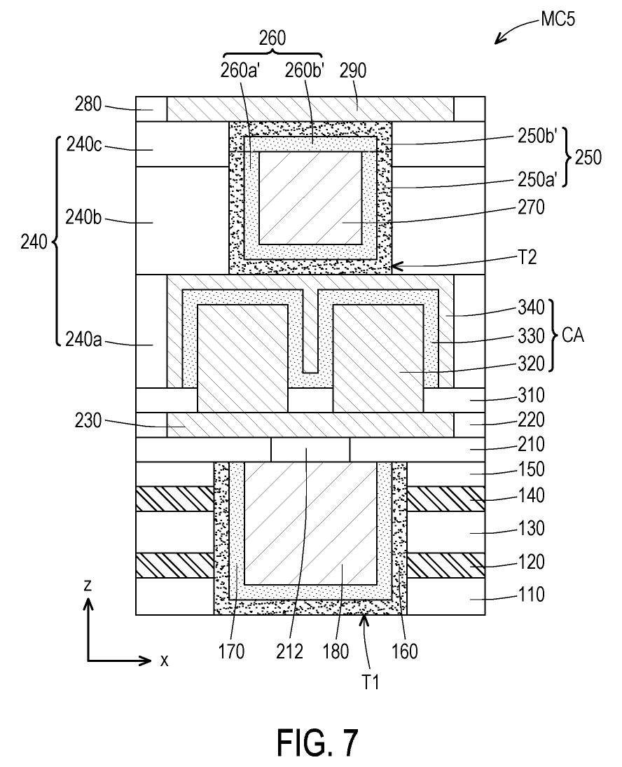

FIG. 7 illustrates a cross-sectional view of a memory cell MC5 according to some embodiments of the present disclosure. The components and some details in FIG. 7 follow those of the embodiments shown in FIGS. 2A-3P, where the same or similar reference numerals are used to denote the same or similar components. The technical content shared with the previous embodiments is omitted for brevity, and the omitted descriptions can be referenced from the earlier embodiments.

The difference between the memory cell MC5 in FIG. 7 and the memory cell MC1 in FIG. 2P lies in that the first electrode 320 in FIG. 7 includes multiple protruding structures. In FIG. 7, the first electrode 320 of each MIM capacitor CA consists of multiple protrusions extending upward from the top surface of the first connection electrode 230. The capacitor insulating layer 330 and the second electrode 340 are formed along the shape of the first electrode 320. In this manner, the capacitance value of the MIM capacitor CA can be enhanced.

In accordance with some embodiments of the present disclosure, a semiconductor device includes a first signal line, a spacer layer, a second signal line, a first transistor, a metal-insulator-metal (MIM) capacitor, and a second transistor. The first signal line, the spacer layer, and the second signal line are stacked along a first direction. The spacer layer is located between the first signal line and the second signal line. The first transistor extends through the first signal line and the second signal line. The MIM capacitor is disposed over the first transistor. The second transistor is disposed over the MIM capacitor. The MIM capacitor is disposed between and electrically connected to the first transistor and the second transistor.

In accordance with some embodiments of the present disclosure, a memory cell includes a first gate electrode, a first layered structure, a second gate electrode, and a second layered structure. The first gate electrode extends along a z direction. The first layered structure is disposed on the first gate electrode. The first layered structure includes a first semiconductor layer and a first gate insulating layer. The first layered structure encircles the first gate electrode in a x-y cross-sectional view. The second gate electrode is disposed over the first gate electrode and extending along a y direction substantially perpendicular to the z direction. The second layered structure is disposed on the second gate electrode. The second layered structure includes a second semiconductor layer and a second gate insulating layer. The second layered structure encircles the second gate electrode in a x-z cross-sectional view. The capacitor is disposed between the first gate electrode and the second electrode in the z direction.

In accordance with some embodiments of the present disclosure, a fabrication method of a semiconductor device includes the following steps. A stack structure including a first signal line, a spacer layer, and a second signal line sequentially stacked along a first direction is formed. A through hole extending through the stack structure is formed. A first transistor is formed in the through hole. A capacitor is formed over the first transistor. A second transistor is formed over the capacitor. The capacitor is disposed between the first transistor and the second transistor in the first direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first signal line, a spacer layer, and a second signal line, stacked along a first direction, wherein the spacer layer is located between the first signal line and the second signal line;
a first transistor, extending through the first signal line and the second signal line;
a metal-insulator-metal (MIM) capacitor, disposed over the first transistor; and
a second transistor, disposed over the MIM capacitor, wherein the MIM capacitor is disposed between and electrically connected to the first transistor and the second transistor.

2. The semiconductor device of claim 1, wherein the first transistor comprises:
a first semiconductor layer, extending through and electrically connected with the first signal line and the second signal line;
a first gate insulating layer, disposed on the first semiconductor layer; and
a first gate electrode, extending along the first direction, wherein the first gate insulating layer is disposed between the first gate electrode and the first semiconductor layer, wherein the first semiconductor layer surrounds the first gate insulating layer and the first gate electrode.

3. The semiconductor device of claim 2, wherein the first semiconductor layer is in contact with a sidewall of the first signal line, a sidewall of the second signal line, and a sidewall of the spacer layer.

4. The semiconductor device of claim 1, wherein the second transistor comprises:
a second gate electrode, extending perpendicular to the first direction;
a second gate insulating layer, surrounding the second gate electrode; and
a second semiconductor layer, surrounding the second gate electrode and the second gate insulating layer.

5. The semiconductor device of claim 4, wherein the second semiconductor layer comprises at least one protrusion at sidewalls of the second semiconductor layer.

6. The semiconductor device of claim 1, further comprising:
an insulating layer disposed between the first transistor and the second transistor;
a conductive via, embedded in the insulating layer over the first gate electrode; and
a connection electrode, electrically connecting the conductive via to the MIM capacitor.

7. The semiconductor device of claim 6, wherein the MIM capacitor comprises:
a first electrode, protruding from a top surface of the connection electrode, wherein a dielectric layer surrounds the first electrode and contacts the top surface of the connection electrode and a sidewall of the first electrode;
a capacitor insulating layer, disposed on the first electrode and in contact with a top surface of the dielectric layer; and
a second electrode, disposed on the capacitor insulating layer.

8. A memory cell, comprising:
a first gate electrode extending along a z direction;
a first layered structure, disposed on the first gate electrode, wherein the first layered structure comprises a first semiconductor layer and a first gate insulating layer, wherein the first layered structure encircles the first gate electrode in a x-y cross-sectional view;
a second gate electrode, disposed over the first gate electrode and extending along a y direction substantially perpendicular to the z direction;
a second layered structure, disposed on the second gate electrode, wherein the second layered structure comprises a second semiconductor layer and a second gate insulating layer, wherein the second layered structure encircles the second gate electrode in a x-z cross-sectional view; and
a capacitor, disposed between the first gate electrode and the second electrode in the z direction.

9. The memory cell of claim 8, further comprising:
a first signal line, a spacer layer, and a second signal line sequentially stacked along the z direction, wherein the first gate electrode extends through the first signal line, the spacer layer, and the second signal line, and the first semiconductor layer is electrically connected to both the first signal line and the second signal line.

10. The memory cell of claim 8, wherein the first gate insulating layer covers sidewalls and a bottom surface of the first gate electrode in the x-z cross-sectional view.

11. The memory cell of claim 8, wherein the capacitor comprises:
a first electrode, electrically connected to the first gate electrode;
a capacitor insulating layer, disposed on the first electrode; and
a second electrode, disposed on the capacitor insulating layer and electrically connected to the second semiconductor layer, wherein the capacitor insulating layer and the second electrode covers sidewalls and a top surface of the first electrode in the x-z cross-sectional view.

12. The memory cell of claim 8, further comprises:
a first signal line and a second signal line; and
a spacer layer, disposed between the first signal line and the second signal line in the z direction, wherein the first signal line and the second signal line are connected to the first semiconductor layer.

13. The memory cell of claim 8, wherein a portion of the second semiconductor layer and a portion of the second gate insulating layer are disposed between the first gate electrode and the second gate electrode.

14. A fabrication method of a semiconductor device, comprising:
forming a stack structure comprising a first signal line, a spacer layer, and a second signal line sequentially stacked along a first direction;
forming a through hole extending through the stack structure;
forming a first transistor in the through hole;
forming a capacitor over the first transistor;
forming a second transistor over the capacitor, wherein the capacitor is disposed between the first transistor and the second transistor in the first direction.

15. The fabrication method of claim 14, wherein forming the second transistor over the capacitor comprises:
forming a first dielectric layer with an opening over the capacitor, wherein the opening is extending perpendicular to the first direction; and
forming a second gate insulating layer, a second semiconductor layer, and a second gate electrode, wherein the second gate insulating layer and the second semiconductor layer surrounds the second gate electrode, wherein the second semiconductor layer is connected to the capacitor.

16. The fabrication method of claim 15, wherein forming the second gate insulating layer, the second semiconductor layer, and the second gate electrode comprises:
forming a first semiconductor material layer in the opening;
forming a first gate insulating material layer on the first semiconductor material layer in the opening;
forming a gate material layer on the first gate insulating material layer in the opening;
removing a portion of the gate material layer outside the opening, with a remaining portion of the gate material layer forming the second gate electrode;
removing a portion of the first gate insulating material layer outside the opening, with a remaining portion of the first gate insulating material layer forming a first portion of the second gate insulating layer;
removing a portion of the first semiconductor material layer outside the opening, with a remaining portion of the first semiconductor material layer forming a first portion of the second semiconductor layer;
forming a second portion of the second gate insulating layer on a top surface of the second gate electrode; and
forming a second portion of the second semiconductor layer on the second portion of the second gate insulating layer.

17. The fabrication method of claim 16, further comprises:
etching the first gate insulating material layer before forming the gate material layer.

18. The fabrication method of claim 16, wherein forming the second portion of the second gate insulating layer on the top surface of the second gate electrode comprises:
forming a second gate insulating material layer on the second gate electrode and the first portion of the second gate insulating layer; and
patterning the second gate insulating material layer to form the second portion of the second gate insulating layer.

19. The fabrication method of claim 16 wherein forming the second portion of the second semiconductor layer on the second portion of the second gate insulating layer comprises:
forming a second semiconductor material layer on the second gate insulating layer and the first portion of the second semiconductor layer; and
patterning the second semiconductor material layer to form the second portion of the second semiconductor layer.

20. The fabrication method of claim 15, wherein forming the capacitor over the first transistor comprises:
forming a first connection electrode over the first gate electrode;
forming a dielectric layer with a hole on the first connection electrode;
forming a first electrode in the hole, wherein the first electrode extending from a top surface of the first connection electrode to beyond a top surface of the dielectric layer;
forming a capacitor insulating layer on the first electrode; and
forming a second electrode on the capacitor insulating layer.
